(19) United States
(12) Patent Application Publication
(10) Pub. No.: US 2012/0280350 A1
(43) Pub. Date: Nov. 8, 2012

(54) BARRIER DEVICE POSITION SENSITIVE DETECTOR

(75) Inventors: Edward Peter Gordon Smith, Santa Barbara, CA (US); Borys Kolasa, Santa Barbara, CA (US)

(73) Assignee: Raytheon Company, Waltham, MA (US)

(21) Appl. No.: 13/099,990

(22) Filed: May 3, 2011

(51) Int. Cl. H01L 27/146; H01L 31/18; H01L 31/0304

(52) U.S. Cl. 257/448; 257/459; 438/98; 257/E31.019; 257/E27.13

(57) ABSTRACT

According to one embodiment, a position sensitive detector (PSD) comprises a plurality of layers, including a substrate layer, an absorber layer, a barrier layer, a sheet layer, and a contact layer. The absorber layer absorbs incident photons such that the absorbed photons excite positive charges and negative charges in the absorber layer. The barrier layer collects a photocurrent from the absorber layer, the photocurrent comprising either the positive charges or the negative charges. The sheet layer provides resistance to control the flow of the photocurrent between a point of incidence of the photons and a plurality of interconnect contacts. The contact layer comprises the interconnect contacts, each interconnect contact operable to conduct the photocurrent to one or more electrical components external to the PSD. The position sensitive detector facilitates determining the point of incidence of the photons according to a relative amount of photocurrent associated with each interconnect contact.

### BACKGROUND

Digital cameras, video cameras, and other image capturing devices may include photodetector circuits to facilitate capturing an image. The photodetector circuits are utilized to sense incident light in the visible and non-visible spectra. Certain photodetector circuits employ one or more position sensitive detectors (PSDs) to measure a position of incident light upon the PSD. Unfortunately, traditional approaches to fabricating PSDs do not readily permit optimizing electrical parameters of the PSDs.

### SUMMARY OF THE DISCLOSURE

According to one embodiment, a position sensitive detector (PSD) comprises a plurality of layers, including a substrate layer, an absorber layer, a barrier layer, a sheet layer, and a contact layer. The absorber layer absorbs incident photons such that the absorbed photons excite positive charges and negative charges in the absorber layer. The barrier layer collects a photocurrent from the absorber layer, the photocurrent comprising either the positive charges or the negative charges. The sheet layer provides resistance to control the flow of the photocurrent between a point of incidence of the photons and a plurality of interconnect contacts. The contact layer comprises the interconnect contacts, each interconnect contact operable to conduct the photocurrent to one or more electrical components external to the PSD. The position sensitive detector facilitates determining the point of incidence of the photons according to a relative amount of photocurrent associated with each interconnect contact.

Some embodiments of the disclosure may provide one or more technical advantages. A technical advantage of certain embodiments may be that a position sensitive detector may be optimized for particular applications and uses. For example, a position sensitive detector may be optimized for use with particular desired wavelengths, including infrared wavelengths. Another technical advantage of certain embodiments may be that sheet resistances and contact resistances associated with a position sensitive detector may be independently optimized. Optimizing the sheet resistances and contact resistances may allow the position sensitive detector to measure a position of incident light more precisely than traditional position sensitive detectors.

Some embodiments may benefit from some, none, or all of these advantages. Other technical advantages may be readily ascertained by one of ordinary skill in the art.

### BRIEF DESCRIPTION OF THE DRAWINGS

For a more complete understanding of the present invention and its features and advantages, reference is now made to the following description, taken in conjunction with the accompanying drawings, in which:

FIG. 1 depicts a simplified schematic diagram illustrating an imaging system, in accordance with embodiments of the present disclosure;

FIG. 2 depicts a simplified schematic diagram illustrating a position sensitive detector that may be used in the imaging system of FIG. 1, in accordance with embodiments of the present disclosure;

FIG. 3 depicts a cross-sectional view of a semiconductor substrate prior to post-processing to form a position sensitive detector, in accordance with certain embodiments of the present disclosure;

FIG. 4A depicts a cross-sectional view of a position sensitive detector fabricated with the semiconductor substrate of FIG. 3, in accordance with certain embodiments of the present disclosure;

FIG. 4B depicts a plan view of the position sensitive detector depicted in FIG. 4A, in accordance with certain embodiments of the present disclosure;

FIG. 5A depicts a perspective view of an array of position sensitive detectors, in accordance with certain embodiments of the present disclosure; and

FIG. 5B depicts a close-up perspective view of the array of position sensitive detectors depicted in FIG. 5A, in accordance with certain embodiments of the present disclosure.

### DETAILED DESCRIPTION OF THE DRAWINGS

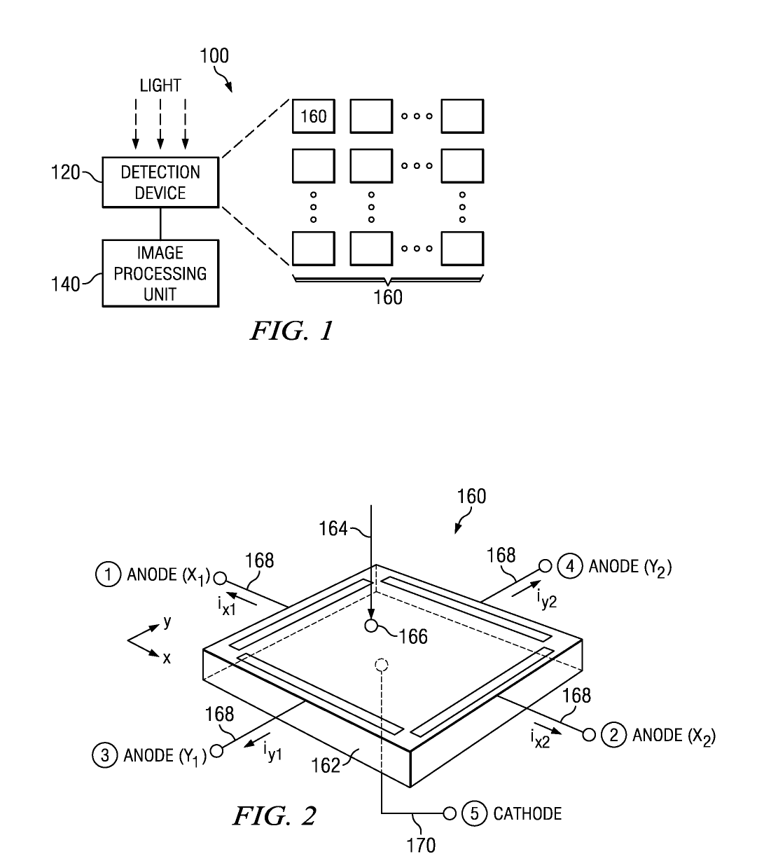

Embodiments of the present invention and its advantages are best understood by referring to FIGS. 1-5 of the drawings, like numerals being used for like and corresponding parts of the various drawings.

FIG. 1 is a block diagram illustrating imaging system 100, in accordance with embodiments of the present disclosure. For example, imaging system 100 may be a digital camera, video camera, or any other photographic and/or image capturing device. Imaging system 100 may include detection device 120 and image processing unit 140. Detection device 120 may be a focal plane array (FPA), active pixel sensor (APS) or any other suitable light sensing device that can capture images. Detection device 120 may include, for example, one or more diodes, charge-coupled devices (CCDs), or any other suitable photovoltaic detectors or transducers. Image processing unit 140 may be a combination of hardware, software, or firmware that is operable to receive signal information from detection device 120 and convert the signal information into an electronic image.

Detection device 120 may include an array of unit cells. Unit cells may accumulate charge or produce a current and/or voltage in response to light incident upon the unit cell and may correspond to a pixel in a captured electronic image. The accumulated charge or the produced current and/or voltage may be used by processing unit 140 for processing of the incident light (e.g., to create an image representative of the incident light). In certain embodiments, one or more of unit cells may include a position sensitive detector 160 (PSD).

FIG. 2 illustrates a PSD 160 that may be used in the imaging system 100 of FIG. 1. PSD 160 may include a semiconductor substrate 162. Illumination 164 may impinge substrate 162 at a point of incidence 166, generating a photocurrent by means of photogeneration of positive and negative charged carriers. Such photocurrent may flow through one or more of anodes 168 and cathode 170 depending upon the location of the point of incidence 166. As the location of point of incidence 166 becomes closer to a particular anode 168, the photocurrent flowing through that anode 168 increases. As the location of the point of incidence 166 becomes further away from the particular anode 168, the photocurrent flowing through that anode 168 decreases. Accordingly, the location of the point of incidence 166 may be computed by analyzing the relative amount of photocurrent associated with each contact ix1, ix2, iy1, and iy2. For example, the location of the point of incidence 166 may be represented by x and y coordinates. The x position may be computed according to the equation x=Kx(ix2−ix1)/(ix2+ix1). The y position may be computed according to the equation y=Ky(iy2−iy1)/(iy2+iy1). Kx and Ky represent scaling constants based on size, electrical characteristics, and other properties of PSD 160.

In certain embodiments, the performance of PSD 160 may be optimized by providing a relatively high level of resistivity across PSD 160 (e.g., along the x and y directions). Increasing the resistivity may cause the current flow through a particular anode 168 to decrease as point of incidence 166 moves away from that anode 168. Thus, the difference between the current flowing through an anode 168 closer to point of incidence 166 and an anode 168 further from point of incidence 166 may increase as resistivity increases. Accordingly, PSD 160 may be able to determine the location of point of incidence 166 more precisely when resistivity is relatively high. In certain embodiments, increasing the resistivity of a sheet layer of PSD 160 may cause resistivity to increase along the x and y directions (e.g., between point of incidence 166 and anodes 168).

In certain embodiments, the performance of PSD 160 may be optimized by providing a relatively low level of resistivity at anodes 168. Decreasing the resistivity at anodes 168 may facilitate providing the flow of current from PSD 160 to external equipment, such as image processing unit 140 of FIG. 1. In certain embodiments, decreasing the resistivity of a contact layer of PSD 160 may cause resistivity to decrease at anodes 168.

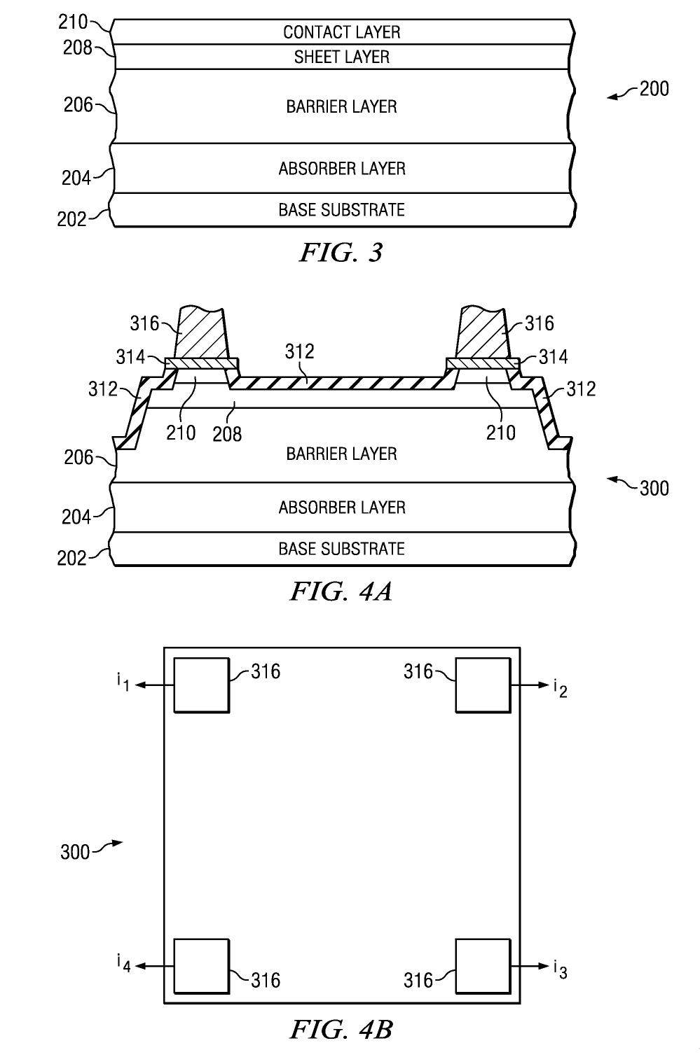

FIG. 3 depicts a cross-sectional view of a semiconductor substrate 200 prior to post-processing to form a PSD, in accordance with certain embodiments of the present disclosure. In certain embodiments, semiconductor substrate 200 may provide a barrier device, such as a minority carrier isotype device or a heterojunction device. As shown in FIG. 3, substrate 200 may include base substrate 202, absorber layer 204, barrier layer 206, sheet layer 208, and contact layer 210.

Base substrate 202 may comprise any substantially intrinsic semiconductor substrate (e.g., purely intrinsic or very lightly-doped), including without limitation silicon, cadmium zinc tellurium, germanium, silicon carbide, aluminum arsenide antimonide, gallium antimonide, gallium arsenide, gallium nitride (GaN), gallium phosphide, indium antimonide, indium arsenide, indium arsenide antimonide, indium gallium arsenide, indium nitride, indium phosphide, mercury cadmium tellurium, silicon germanium, or other suitable semiconductor material. The material or materials used for base substrate 202 may be selected based on desired characteristics for a PSD to be fabricated from substrate 200 (e.g., a material may be selected based on having lattice properties similar to that of absorber layer 204 to be deposited on base substrate 202).

Absorber layer 204 may be operable to absorb incident photons such that the absorbed photons excite positive charges and negative charges in absorber layer 204. Absorber layer 204 may comprise any substantially doped semiconductor substrate (e.g., dopant concentration between approximately 5×1014 cm-3 and approximately 5×1017 cm-3), including without limitation the semiconductors set forth above with respect to base substrate 202. In certain embodiments, absorber layer 204 may include either an n-type semiconductor substrate or a p-type semiconductor substrate. The material or materials used for absorber layer 204 may be selected based on desired characteristics for the PSD (e.g., a material may be selected with a bandgap suitable for photon absorption, and thus light detection, of a particular wavelength or range of wavelengths). In certain embodiments, absorber layer 204 may be grown to a thickness of between approximately 1.0 μm and approximately 15.0 μm (e.g., to ensure absorber layer 206 is sufficiently thick to capture light of a particular intensity).

Barrier layer 206 may be operable to collect a photocurrent from absorber layer 204. The photocurrent may comprise either the positive charges or the negative charges and depends on whether the absorber is an n-type or p-type semiconductor. Barrier layer 206 may comprise any doped or undoped semiconductor substrate, including without limitation the semiconductors set forth above with respect to base substrate 202. In certain embodiments, the dopant concentration may be between approximately 5×1014 cm-3 and approximately 5×1017 cm-3. In certain embodiments, barrier layer 206 may comprise the same type of doping as absorber layer 204 (e.g., either both layers comprise n-type doping or both layers comprise p-type doping). Alternatively, barrier layer 206 may comprise a different type of doping than absorber layer 204 (e.g., absorber layer 204 may comprise n-type doping and barrier layer 206 may comprise p-type doping, or vice versa). In certain embodiments, barrier layer 206 may be grown to a thickness of between approximately 0.05 μm and approximately 2.0 μm. The material or materials used for barrier layer 206, the dopant concentration of barrier layer 206, the thickness of barrier layer 206, and/or other physical characteristics of barrier layer 206 may be selected based on desired characteristics for the PSD. For example, certain physical characteristics of barrier layer 206 may be selected to form an electrical separation between sheet layer 208 and contact layer 210. By decoupling sheet layer 208 from contact layer 210, each layer may be optimized independently of the other. As an example, the resistivity of sheet layer 208 may be increased to an optimal level without substantially increasing the resistivity of contact layer 210. Similarly, the resistivity of contact layer 210 may be decreased to an optimal level without substantially decreasing the resistivity of sheet layer 208.

Sheet layer 208 may be operable to provide resistance to control the flow of the photocurrent between a point of incidence of the photons and a plurality of contacts. Sheet layer 208 may comprise any doped or undoped semiconductor substrate, including without limitation the semiconductors set forth above with respect to base substrate 202. In certain embodiments, the dopant concentration may be between approximately 5×1014 cm-3 and approximately 5×1016 cm-3. In certain embodiments, sheet layer 208 may comprise the same type of doping as absorber layer 204 (e.g., either both layers comprise n-type doping or both layers comprise p-type doping). Alternatively, sheet layer 208 may comprise a different type of doping than absorber layer 204 (e.g., absorber layer 204 may comprise n-type doping and sheet layer 208 may comprise p-type doping, or vice versa). In certain embodiments, sheet layer 208 may be grown to a thickness of between approximately 0.1 μm and approximately 2.0 μm. The material or materials used for sheet layer 208, the dopant concentration of sheet layer 208, the thickness of sheet layer 208, and/or other physical characteristics of sheet layer 208 may be selected based on desired characteristics for the PSD. For example, certain physical characteristics may be selected based on a desired resistivity for sheet layer 208.

Contact layer 210 may comprise the plurality of contacts. Each contact may be operable to conduct the photocurrent to one or more electrical components external to the PSD. Contact layer 210 may comprise any highly-doped semiconductor substrate (e.g., dopant concentration between approximately 5×1016 cm-3 and approximately 5×1018 cm-3), including without limitation the semiconductors set forth above with respect to base substrate 202. In certain embodiments, contact layer 210 may comprise the same type of doping as absorber layer 204 (e.g., either both layers comprise n-type doping or both layers comprise p-type doping). Alternatively, contact layer 210 may comprise a different type of doping than absorber layer 204 (e.g., absorber layer 204 may comprise n-type doping and contact layer 210 may comprise p-type doping, or vice versa). In certain embodiments, contact layer 210 may be grown to a thickness of between approximately 0.1 μm and approximately 2.0 μm. The material or materials used for contact layer 210, the dopant concentration of contact layer 210, the thickness of contact layer 210, and/or other physical characteristics of contact layer 210 may be selected based on desired characteristics for the PSD. For example, certain physical characteristics may be selected based on a desired resistivity for contact layer 210.

As described above, the materials for each layer may be selected based on desired characteristics of the PSD. In certain embodiments, the layers may comprise III-V materials. The III-V materials may include at least a first element found in group III of the periodic table and a second element found in group V of the periodic table. Group III elements may have three electrons in their outer-most electronic shell, examples include boron, aluminum, gallium, indium, and thallium. Group V elements may have five electrons in their outer-most electronic shell, examples include nitrogen, phosphorus, arsenic, antimony, and bismuth. For example, base substrate 202 may comprise gallium antimonide, absorber layer 204 may comprise indium arsenide antimonide, barrier layer 206 may comprise aluminum arsenide antimonide, sheet layer 208 may comprise indium arsenide antimonide, and contact layer 210 may comprise indium arsenide antimonide. In certain embodiments, materials comprising antimonide or mercury cadmium tellurium may be well-suited to a PSD designed to detect infrared light. In certain embodiments, materials comprising indium gallium arsenide or silicon germanium may be well-suited to a PSD designed to detect visible light.

After one or more of the various layers described above have been formed, substrate 200 may be used to fabricate one or more PSDs, as described in greater detail below.

FIGS. 4A and 4B depict different views of a PSD 300 fabricated using semiconductor substrate 200 of FIG. 3, in accordance with certain embodiments of the present disclosure. FIG. 4A depicts a cross-sectional view and FIG. 4B depicts a plan view. As shown in FIG. 4A, PSD 300 may include base substrate 202, absorber layer 204, barrier layer 206, sheet layer 208, and contact layer 210 depicted in FIG. 3 and described above. In addition, PSD 300 may include passivation 312, contact metal 314, and interconnect contacts 316.

To fabricate PSD 300 from semiconductor substrate 200, portions of absorber layer 204, barrier layer 206, sheet layer 208, and contact layer 210 may be etched from substrate 200 using any suitable etching technique (e.g., wet chemical etching or dry plasma etching). Portions of absorber layer 204 may be etched, for example, to delineate and/or electrically isolate adjacent pixels from each other. Portions of sheet layer 208 may be etched to, for example, optimize characteristics of PSD 300 (e.g., resistivity of the portion of sheet layer 208 of PSD 300) and/or define a pixel area for PSD 300 (e.g., for when a PSD 300 is used as a unit cell in an array of PSDs 300). Portions of contact layer 210 may to etched to, for example, define one or more areas of substrate 200 to be electrically coupled to other electrical and/or electronic circuitry external to PSD 300.

After portions of portions of absorber layer 204, barrier layer 206, sheet layer 208, and contact layer 210 have been etched from substrate 200, passivation 312 may be deposited on top of the exposed portions of absorber layer 204, barrier layer 206, sheet layer 208, and contact layer 210. Passivation 312 may include silicon dioxide, cadmium telluride or any other suitable material. Passivation 312 may be deposited on substrate 200 via thermal evaporation, chemical vapor deposition, atomic layer deposition, molecular beam epitaxy, or any other suitable method. After depositing passivation 312, portions of passivation 312 may be removed (e.g., via wet chemical etching or dry plasma etching in order to expose the remaining portions of contact layer 210). Passivation 312 may serve to prevent contact metal 314, interconnect contacts 316, and other materials from interacting with portions of substrate 200.

Contact metal 314 may be formed on portions of remaining contact layer 210 not covered by passivation 312 and may include a generally conductive material (e.g., aluminum, silver, copper, gold, or other suitable metal) to electrically couple contact layer 210 to corresponding interconnect contacts 316 and/or other electrical and/or electronic circuitry external to PSD 300. Contact metal 314 may be formed on substrate 200 via implantation, deposition, epitaxy, or any other suitable fabrication technique. For example, contact metal 314 may be formed by depositing aluminum upon substrate 200 and etching away those portions of the deposited aluminum which are not proximate to remaining portions of contact layer 210.

Interconnect contacts 316 may each be coupled to a corresponding portion of contact metal 314 and may include a generally conductive material (e.g., indium or other suitable metal) to electrically couple its corresponding contact metal 314 to other electrical and/or electronic circuitry external to PSD 300. Interconnect contacts 316 may be formed on substrate 200 via any suitable fabrication technique. For example, contact 212 may be formed by plating or thermal deposition.

As shown in FIG. 4B, PSD 300 may include four interconnect contacts 316 (which may themselves be coupled to corresponding contact metals 314 and portions of contact layer 210) that may in effect serve as electrical terminals (e.g., anodes) for PSD 300. Although not depicted, PSD 300 may also include an electrical terminal (e.g., a cathode) electrically coupled to absorber layer 206 or base substrate 202. For example, in embodiments where PSD 300 is an integral part of an array of identical or similar PSDs, such PSDs may include common elements (e.g., common absorber layer 204, common base substrate 202) that may be coupled to a common electrical terminal (e.g., a cathode at the periphery of the PSD array). Accordingly, in operation of PSD 300, photons absorbed by absorber layer 206 may generate a photocurrent which may flow through one or more of the interconnect contacts 316 as currents i1, i2, i3, and i4. By measuring the currents i1, i2, i3, and i4, a position of light incident upon PSD 300 (or the presence of light incident upon PSD 300) may be determined.

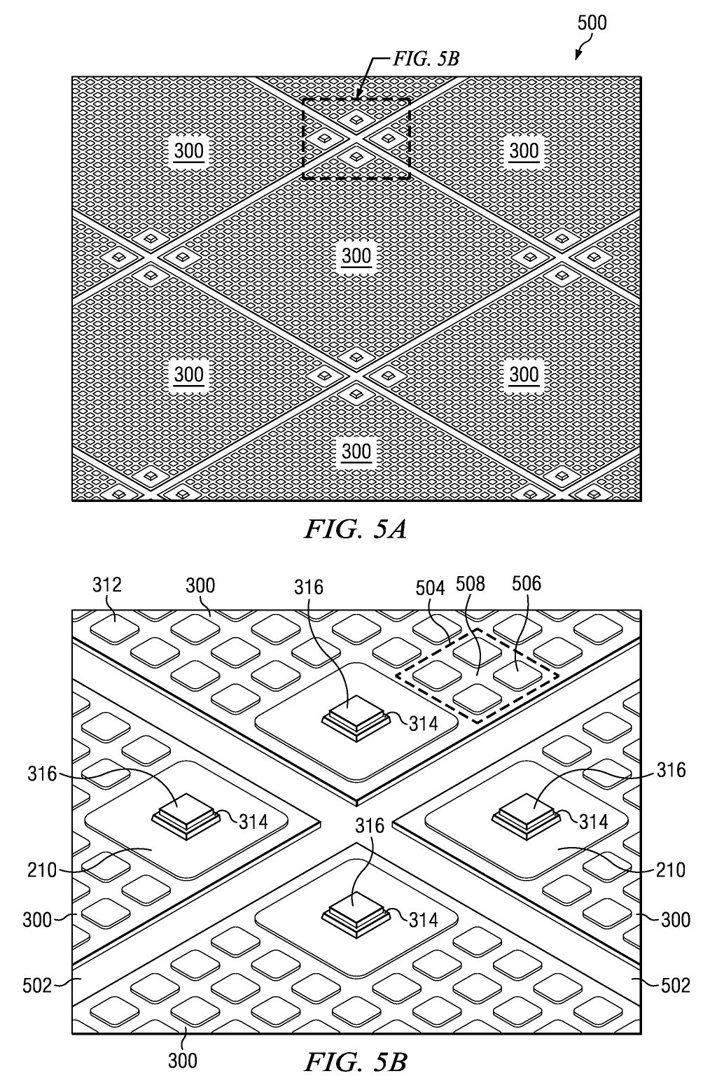

FIG. 5A depicts a perspective view of an array 500 of position sensitive detectors 300, in accordance with certain embodiments of the present disclosure. FIG. 5B depicts a close-up perspective view of the array 500 depicted in FIG. 5A. Array 500 may comprise a focal plane array (FPA) and/or any other suitable imaging device. As depicted in FIGS. 5A and 5B, array 500 may include a plurality of PSDs 300, mesa delineation 502 and grid delineation 504.

In certain embodiments, array 500 of PSDs 300 may be formed from a single semiconductor substrate (e.g., substrate 200). In such embodiments, certain portions of one or more PSDs 300 may be common to each other. For example, each PSD 300 in array 500 may have a common base substrate 202 and a common absorber layer 204. In addition, each individual PSD 300 of array 500 may have its own sheet layer 208, its own contact layer 210, and its own interconnect contacts 316 defining a pixel in array 500.

In certain embodiments, mesa delineation 502 may be used to define individual PSDs 300/pixels in array 500. Mesa delineation 502 may be formed by selectively etching portions of certain layers, such as contact layer 210, sheet layer 208, barrier layer 206, and/or absorber layer 204.

Grid delineation 504 may be formed by selectively etching portions of sheet layer 208 to form a grid, other shape, pattern, and/or collection of features. For example, grid delineation 504 may be formed after etching of contact layer 210, and may be formed via wet chemical etching or dry plasma etching. In the same manner, an alternative implementation of grid delineation may be ion implantation to selectively change the resistivity of the material in the form of a grid, other shape, pattern, and/or collection of features. In FIGS. 5A and 5B, the grid delineation of sheet layer 208 may be covered by passivation 312. As depicted in FIGS. 5A and 5B, grid delineation 504 may be formed by creating a plurality of raised features 506 and a plurality of troughs 508. The physical dimensions of grid delineation 504 (e.g., the height, length, and/or width of raised features 506 and/or the width and/or depth of troughs 508) may be selected based on desired characteristics for PSDs 300 making up array 500 (e.g., selected physical characteristics may be selected based on a desired resistivity for the portion of sheet layer 208 remaining in each PSD 300).

Some embodiments of the disclosure may provide one or more technical advantages. A technical advantage of certain embodiments may be that a position sensitive detector may be optimized for particular applications and uses. For example, a position sensitive detector may be optimized for use with particular desired wavelengths, including infrared wavelengths.

In certain embodiments a barrier layer may decouple the sheet layer and the contact layer. Accordingly, sheet resistances and contact resistances associated with the position sensitive detector may be independently optimized. For example, the sheet layer materials, doping type, dopant concentration, and other characteristics affecting the sheet resistance may be determined independently of the contact layer materials, doping type, dopant concentration, and other characteristics affecting the contact resistance. Thus, a relatively wide range of materials and design characteristics may be used. Optimizing the sheet resistances and contact resistances may allow the position sensitive detector to measure a position of incident light more precisely than traditional position sensitive detectors.

Although the embodiments in the disclosure have been described in detail, numerous changes, substitutions, variations, alterations, and modifications may be ascertained by those skilled in the art. Additionally or alternatively, while certain embodiments of the disclosure have been described with reference to infrared detectors, the embodiments disclosed herein may be utilized with many types of detectors including, but not limited to, visible, infrared, ultraviolet, x-ray, or other radiation detectors. It is intended that the present disclosure encompass all such changes, substitutions, variations, alterations and modifications as falling within the spirit and scope of the appended claims.

Modifications, additions, or omissions may be made to the methods described without departing from the scope of the invention. The methods may include more, fewer, or other steps. Additionally, steps may be performed in any suitable order.

Although this disclosure has been described in terms of certain embodiments, alterations and permutations of the embodiments will be apparent to those skilled in the art. Accordingly, the above description of the embodiments does not constrain this disclosure. Other changes, substitutions, and alterations are possible without departing from the spirit and scope of this disclosure, as defined by the following claims.

What is claimed is:

1. An apparatus comprising:
a position sensitive detector (PSD) comprising a plurality of layers, the plurality of layers including:
a substrate layer;
an absorber layer deposited outwardly from the substrate layer, the absorber layer operable to absorb incident photons such that the absorbed photons excite positive charges and negative charges in the absorber layer;
a barrier layer deposited outwardly from the absorber layer, the barrier layer operable to collect a photocurrent from the absorber layer, the photocurrent comprising either the positive charges or the negative charges;
a sheet layer deposited outwardly from the barrier layer, the sheet layer operable to provide resistance to control the flow of the photocurrent between a point of incidence of the photons and a plurality of interconnect contacts; and
a contact layer deposited outwardly from the sheet layer, the contact layer comprising the plurality of interconnect contacts, each interconnect contact operable to conduct the photocurrent to one or more electrical components external to the PSD; and
the position sensitive detector operable to facilitate determining the point of incidence of the photons according to a relative amount of photocurrent associated with each interconnect contact.

2. The apparatus of claim 1, wherein the barrier layer forms an electrical separation between the sheet layer and the contact layer such that a level of resistance of the sheet layer may be selected substantially independently of a level of resistance of the contact layer.

3. The apparatus of claim 1, the absorber layer comprising a semiconductor material selected to absorb photons of infrared wavelengths.

4. The apparatus of claim 1, wherein a doping type of the absorber layer matches a doping type of the contact layer, the doping type comprising an n-type doping or a p-type doping.

5. The apparatus of claim 1, wherein the barrier layer comprises an undoped layer.

6. The apparatus of claim 1, the plurality of layers comprising III-V semiconductor materials.

7. The apparatus of claim 1, the substrate layer comprising at least one of gallium and antimony.

8. The apparatus of claim 1, the absorber layer comprising at least one of indium, arsenic, and antimony.

9. The apparatus of claim 1, the barrier layer comprising at least one of aluminum, arsenic, and antimony.

10. The apparatus of claim 1, the contact layer comprising at least one of indium, arsenic, and antimony.

11. The apparatus of claim 1, at least one of the layers comprising at least one of gallium, antimony, indium, arsenic, aluminum, mercury, cadmium, tellurium, silicon, and germanium.

12. A system comprising:
a plurality of position sensitive detectors (PSDs), each PSD comprising a plurality of layers, the plurality of layers including:
a substrate layer;
an absorber layer deposited outwardly from the substrate layer, the absorber layer operable to absorb incident photons such that the absorbed photons excite positive charges and negative charges in the absorber layer;
a barrier layer deposited outwardly from the absorber layer, the barrier layer operable to collect a photocurrent from the absorber layer, the photocurrent comprising either the positive charges or the negative charges;
a sheet layer deposited outwardly from the barrier layer, the sheet layer operable to provide resistance to control the flow of the photocurrent between a point of incidence of the photons and a plurality of interconnect contacts; and
a contact layer deposited outwardly from the sheet layer, the contact layer comprising the plurality of interconnect contacts, each interconnect contact operable to conduct the photocurrent to one or more electrical components external to the PSD; and
a processing unit communicatively coupled to the plurality of PSDs, the processing unit operable to:
determine the point of incidence of the photons according to a relative amount of photocurrent associated with each interconnect contact; and
generate an image according to the point of incidence of the photons.

13. The system of claim 12, wherein the barrier layer forms an electrical separation between the sheet layer and the contact layer such that a level of resistance of the sheet layer may be selected substantially independently of a level of resistance of the contact layer.

14. The system of claim 12, the absorber layer comprising a semiconductor material selected to absorb photons of infrared wavelengths.

15. The system of claim 12, the plurality of layers comprising III-V semiconductor materials.

16. A method of manufacturing a position sensitive detector (PSD), comprising:
depositing an absorber layer on a semiconductor substrate, the absorber layer operable to absorb incident photons such that the absorbed photons excite positive charges and negative charges in the absorber layer;
depositing a barrier layer on the absorber layer, the barrier layer operable to collect a photocurrent from the absorber layer, the photocurrent comprising either the positive charges or the negative charges;
depositing a sheet layer on the barrier layer, the sheet layer operable to provide resistance to control the flow of the photocurrent between a point of incidence of the photons and one or more interconnect contacts;
depositing a contact layer on the sheet layer, the contact layer comprising the one or more interconnect contacts; and
defining the one or more interconnect contacts of the contact layer, each of the one or more interconnect contacts operable to conduct the photocurrent to one or more electrical components external to the semiconductor substrate.

17. The method of claim 16, further comprising selecting a substrate layer material, the substrate layer material comprising at least one of gallium and antimony.

18. The method of claim 16, further comprising selecting an absorber layer material, the absorber layer material comprising at least one of indium, arsenic, and antimony.

19. The method of claim 16, further comprising selecting a barrier layer material, the barrier layer material comprising at least one of aluminum, arsenic, and antimony.

20. The method of claim 16, further comprising selecting a contact layer material, the contact layer material comprising at least one of indium, arsenic, and antimony.
